(19) United States
(12) Patent Application Publication
(10) Pub. No.: US 2015/0295180 A1
(43) Pub. Date: Oct. 15, 2015

(54) COMPOSITION FOR ACTIVE LAYER OF TERNARY ORGANIC SOLAR CELL, CONTAINING A LOW CONTENT OF FULLERENE-BASED MOLECULE

(71) Applicant: Kyungpook National University Industry-Academic Cooperation Foundation, Daegu (KR)

(72) Inventors: Youngkyoo Kim, Daegu (KR); Hwajeong Kim, Daegu (KR); Sungho Nam, Daegu (KR)

(21) Appl. No.: 14/612,970

(22) Filed: Feb. 3, 2015

(30) Foreign Application Priority Data
Apr. 9, 2014 (KR) 10-2014-0042546

(51) Int. Cl. H01L 51/00; H01L 51/44

(52) U.S. Cl. CPC H01L 51/0036; H01L 51/0046; H01L 51/441

(57) ABSTRACT

Solar cells according to the present invention form a bulk heterojunction (BHJ) active layer using a first polymer, a second polymer and a first small molecule, having energy structures as shown in FIG. 2, in which the second polymer plays a charge-bridging role. As such, even if the content of the first small molecule is reduced for increasing the lifetime of solar cell, the power conversion efficiency (PCE) of solar cells can be greatly increased. Further, the size of the first small molecule aggregates on the surface of thin film can be increased, thereby leading to a change in nanostructure of the BHJ active layer.

### TECHNICAL FIELD

The present invention relates to a composition for an active layer of ternary organic solar cell containing a low content of fullerene-based content; a solar cell of which the active layer is formed thereof; and a kit for forming the active layer of organic solar cells.

### BACKGROUND ART

As the depletion of conventional energy resources such as coal and oil has recently been predicted, there is a growing interest in energy which can replace them. Especially, solar cells have been the focus of the growing interest for being enriched in energy resources and eco-friendly.

Solar cells include solar thermal collectors which generate steam required for rotating a turbine by solar heating, and solar photoelectric cells which convert photons into electrical energy using properties of a semiconductor. Commonly, solar cells refer to solar photoelectric cells.

Most commercialized solar cells are inorganic solar cells using inorganic materials such as monocrystalline silicon, polycrystalline silicon, and amorphous silicon. However, these inorganic solar cells are not suitable for a household use since the manufacturing process is complex, and thus the manufacturing cost is high. As such, research is actively conducted on organic solar cells which require a low manufacturing cost due to a relatively simple manufacturing process compared to the manufacturing process of inorganic solar cells.

Also, organic solar cells have advantages of having a thin film of less than 100 nm in thickness and of applying as a flexible structure. Thus, various applications of organic solar cells are expected, such as a potential future energy source for portable information systems, etc.

A general structure of organic solar cells include a lower electrode layer formed on a substrate, a hole transport layer formed in contact with the surface of the lower electrode layer, at least one active layer formed in contact with the surface of the hole transport layer, and an upper electrode layer formed on the active layer (see FIG. 1). If the light is projected to the organic solar cell, excitons (hole-electron pair) are generated in the active layer, the electrons are moved to the upper electrode of the active layer, and the holes are moved to the hole transport layer. The active layer of conventional organic solar cells has been manufactured using a mixture of an electron donating material, poly(3-hexylthiophene)(P3HT), and an electron accepting material, 1-(3-methoxycarbonyl)-propyl-1-phenyl-(6,6)C₆₁(1-(3-methoxycarbonyl)-propyl-1-phenyl(6,6)C₆₁ (PCBM).

Meanwhile, the performance of the polymer:fullerene solar cells has been greatly improved by employing new conjugated polymers and optimizing device structures since early breakthroughs for bulk heterojunction (BHJ) solar cells. To date, the highest power conversion efficiency (PCE) has reached ˜9.2% for single stack polymer:fullerene solar cells and ˜10.6% for tandem polymer:fullerene solar cells. The improved performance can be attributed to the enhanced open circuit voltage (Voc) due to the high-lying highest occupied molecular orbital (HOMO) energy levels of new conjugated polymers, while the enhanced light harvesting effect is explained to be due to their extended optical absorption ranges toward near infrared wavelengths.

However, even through new conjugated polymers could may provide such high PCEs, the stability (lifetime) of polymer:fullerene solar cells is still a big challenging point. Several reasons have been suggested for the low stability of polymer:fullerene solar cells, which include erosion effect by acidity of the hole-collecting buffer layer, interfacial degradation between active layers and metal electrodes, light-induced degradation of conjugated polymers (excited states), gradual demixing between conjugated polymers and soluble fullerenes, etc. Of such reasons, both the degradation of conjugated polymers and the demixing between conjugated polymers and fullerenes (morphological instability) under continuous solar light illumination may be the most challenging parts in order to secure the stability of polymer-based solar cells.

The demixing phenomenon between conjugated polymers and fullerenes can be attributed to the intrinsic nature of fullerenes which are small molecules with a tendency to undergo crystallization once activation energy such as solar light is given. Hence, in order to minimize the influence of the morphological instability owing to the phase demixing in the polymer-fullerene BHJ films, reducing the fullerene content can be one of the realistic approaches when it comes to the probability for the demixing events. However, the low fullerene content gives rise to poor device performances because of the insufficient charge (electron) percolation paths generated in the BHJ films (active layers). For example, in order to achieve a reasonable PCE (>2.5%), the fullerene content should be higher than 0.7 part by weight (ca. 41 wt. %) for poly(3-hexylthiophene) (P3HT) and [6,6]-phenyl-C₆₁-butyric acid methyl ester (PC₆₁BM) (i.e., P3HT:PC₆₁BM=1:0.7 by weight).

### DISCLOSURE OF INVENTION

### Technical Problem

The present inventors have discovered that the performance of polymer:fullerene with low fullerene contents can be greatly improved by adding a charging-bridging polymer thereto. The present invention is based on this discovery.

Therefore, the objective of the present invention is to provide a combination of a first polymer, a second polymer and a first small molecule, having HOMO/LUMO energy structures which easily move and harvest charges on the active layer of solar cells, so that excellent power conversion efficiency (PCE) can be exerted, while reducing a content of small molecules determining the lifetime of solar cells, such as fullerene which tends to undergo crystallization once an activation energy such as solar light is given.

### Technical Solution to Problem

In order to achieve the objective, a first aspect of the present invention provides a composition for an active layer of organic solar cells comprising a first polymer which absorbs light to form an exciton, a second polymer which plays a charge-bridging role, and a first small molecule which is an electron accepting material, wherein:

LUMO energy level of the second polymer is present between LUMO energy level of the first polymer and LUMO energy level of the first small molecule;

HOMO energy level of the second polymer is present between HOMO energy level of the first polymer and HOMO energy level of the first small molecule; and

the content of the first small molecule is 10 wt. %˜45 wt. % of the total weight of the first polymer, the second polymer, and the first small molecule.

The second aspect of the present invention provides organic solar cells in which an active layer is disposed between two electrodes,

the active layer comprising a first polymer which absorbs light to form excitons, a second polymer which plays a charge-bridging role, and a first small molecule which is an electron accepting material, wherein:

LUMO energy level of the second polymer is present between LUMO energy level of the first polymer and LUMO energy level of the first small molecule;

HOMO energy level of the second polymer is present between HOMO of the first polymer and HOMO energy level of the first small molecule; and the content of the first small molecule is 10 wt. %˜45 wt. % of the total weight of the first polymer, the second polymer, and the first small molecule.

The third aspect of the present invention provides a kit for forming the active layer of organic solar cells, comprising a first polymer which absorbs light to form excitons, a second polymer which plays a charge-bridging role, a first small molecule which is an electron accepting material, wherein:

LUMO energy level of the second polymer is present between LUMO energy level of the first polymer and LUMO energy level of the first small molecule; and

HOMO energy level of the second polymer is present between HOMO energy level of the first polymer and HOMO energy level of the first small molecule.

Hereinafter, the present invention is described in more detail.

When light enters organic solar cells, the light is absorbed in an electron donating material to form an electron-hole pair called an exciton which is energy under an excited state. When this exciton diffuses in any direction and encounters the interface with the electron accepting material, it is separated into an electron and a hole. The electron accepting material pulls electrons and induces a charge separation. The hole remaining in the electron donating layer is moved to an anode, and the electron in the electron accepting layer is moved into a cathode, thus flowing in the form of electric current. When such electron flow is continuously generated, a current and voltage can be generated, thereby converting light energy into electrical energy.

Organic solar cells mainly absorb light in a polymeric substance and form an exciton (hole-electron pair). However, the exciton has high binding energy due to a low dielectric constant of the polymeric material. In order to overcome this binding energy, it is possible to lead the charge separation of the exciton only by providing the LUMO energy level difference of more than 0.3 eV˜0.5 eV. That is, only when energy offset of 0.3 eV˜0.5 eV exists, the charge of the exciton is separated, thereby moving electrons into an electron accepting substance. Thus, the electron is moved into the cathode, whereas the hole is moved into the anode.

PCBM which is mainly used as an electron accepting small molecule has a disadvantage of being expensive and leads to a life reduction due to demixing caused by heat or time. For example, a fullerene has tendency to undergo crystallization once activation energy such as the solar light is given.

Accordingly, the features of the present invention are that an electron accepting small molecular is used in a small amount unlike a conventional technique (greater than 50 wt. %, usually 70 wt. %) and that, in order to overcome a reduction of a charge separation/transport efficiency due to the use of a small amount of the electron accepting material, a charge-bridging polymer is further used in the active layer of solar cells. Preferably, the charge-bridging polymer can play a role in enhancing absorption of light and facilitating the movement of charges.

In one embodiment of the present invention, it has been attempted to add a charge-bridging polymer to polymer:fullerene BHJ films in order to improve the performance of polymer:fullerene solar cells with low fullerene contents. Although various kinds of ternary blend approaches have been tried for typically high fullerene contents, no attempts has been made to add charge-bridging polymers to the polymer:fullerene BHJ films with low fullerene contents.

In one embodiment of the present invention (FIG. 3), P3HT:PC₆₁BM (1:0.5˜33.3 wt. %) films have been selected as a model system to support the present invention, because the PCE of the corresponding solar cells is as low as <0.5% compared to high PCE for typical P3HT: PC61BM solar cells with high PC₆₁BM contents (>2.5% PCE depending on supplier batches of P3HT materials). As the charge-bridging polymer, poly[(4,8-bis-(2-ethylhexyloxy)-benzo[1,2-b:4,5-b′]dithiophene)-2,6-diyl-alt-(N-2-ehtylhexylthieno[3,4-c]pyrole-4,6-dione)-2,6-diyl]](PBDTTPD) was selected, because its band gap (1.8 eV) is close to that of the P3HT film (1.9 eV) so that the influence of exciton (Forster) energy transfer from P3HT to the charge-bridging polymer can be minimized to exactly investigate charge separation and transport effects inside the BHJ films.

In order for the second polymer to play a charge-bridging role between the first polymer which absorbs the light and forms an exciton, and the first small molecule which is an electron accepting material, it is preferable that LUMO of the second polymer is present between LUMO of the first polymer and LUMO of the first small molecule, and that HOMO of the second polymer is present between HOMO of the first polymer and HOMO of the first small molecule. That is, in accordance with the present invention, the first polymer, the second polymer, and the first small molecule preferably have the energy levels as shown in FIG. 2. If the first polymer, the second polymer and the first small molecule have such energy levels, the charge separation can be enhanced, and VOC can be increased. The second polymer having the energy level shown in FIG. 2 can primarily take electrons from the first polymer through charge separation process and then deliver electrons to the first small molecule through charge transport process. At the same time, the hole transport follows in the opposite direction of the electron transport. Accordingly, the second polymer can play a bridge role for charge transfer/transport between the first polymer and the first small molecule.

In addition, the second polymer which plays a charge-bridging role can also absorb solar light, and photo-generated electrons can be transferred to the first small molecule, wherein the number of electrons depends on the content of the second polymer. Similarly, the photo-generated hole in the second polymer can be transferred to the first polymer.

The content of the second polymer is preferably 10 wt. % 60 wt. % of the total weight of the first polymer, the second polymer, and the first small molecule.

When the second polymer is added in an amount of less than or equal to 5 wt. %, J_{SC} and V_{OC} can become even worse. On the other hand, if the second polymer is added in an amount of more than or equal to 10 wt. %, the J_{SC} and V_{OC} values can be increased. The maximum values of the J_{SC} and V_{OC} can be given in the range of 10 wt. %˜60 wt. %. Further, although the J_{SC} and V_{OC} values are low, the PCE performance is excellent. This is because the second polymer plays an efficient bridging role in transferring electrons from the first polymer to the first small molecule.

Further, the second polymer can additionally contribute to V_{OC} increase, which is theoretically possible if the electrons in the second polymer are directly collected in the electrode (FIG. 4). Also, the second polymer can enhance the electron transport by a synergistic effect with the first small molecule.

Although a charge separation can occur between the first polymer and the first small molecule, an additional charge separation may occur even between the first polymer and the second polymer. Accordingly, as the content of the second polymer increases, the charge separation (charge transfer from the first polymer to the second polymer) can be efficiently made.

The first small molecule is slightly concentrated toward the surface of films by adding the second polymer, thereby forming an aggregate of the first small molecule. This leads to a coarse morphology, thereby better facilitating the electron transport. Furthermore, the second polymer may lead to the concentration of the first small molecule toward the surface of films, thereby leading to a better vertical alignment of the p-n conjugate. Additionally, stacking of the first polymer can be destroyed by the second polymer, increasing the performance of solar cells.

The first polymer is not limited to the material as long as the active layer absorbs light to form an exciton. Non-limiting examples of the first polymer may include poly(3-hexylthiophene)(P3HT), poly(3-alkylthiophene)(P3AT), poly(3-octylthiophene (below, called “P3OT”), poly(2-methoxy-5-(2′-ethylhexyloxy)-p-phenylene)vinylene (MEH-PPV), poly{2-methoxy-5-[(3,7-dimethyloctyl)oxy]phenylene}vinylene (MDMO-PPV), etc. Preferably, it may be MDMO-PPV, P3HT, and PFB.

The electron accepting material has a high electron affinity and mainly serves to pull the electrons to induce a separation of electrons and holes. The electrons in the electron accepting material are transported by moving to the cathode along the electron accepting material.

The first small molecule is not limited to a material as long as it is an electron accepting material. Non-limiting examples of the first small molecule may include fullerene derivatives such as 1-(3-methoxycarbonyl)-propyl-1-phenyl-(6,6)C₆₁ (PC₆₁61BM), 1-(3-methoxycarbonyl)-propyl-1-phenyl-(6,6)C₇₀ (PC₇₀BM), 1-(3-methoxycarbonyl)-propyl-1-phenyl-(6,6)C₈₄ (PC₈₄BM), etc. PC₆₀BM, PC₇₀BM, and ICBA are preferred.

The second polymer which plays a charge-bridging role between the first polymer and the first small molecule is not limited to a material. Non-limiting examples of the second polymer may include PCPDTBT, PCDTBT, Si-PCPDTBT, PBDTTPD, PBDT(X)TPD, and F8TBT.

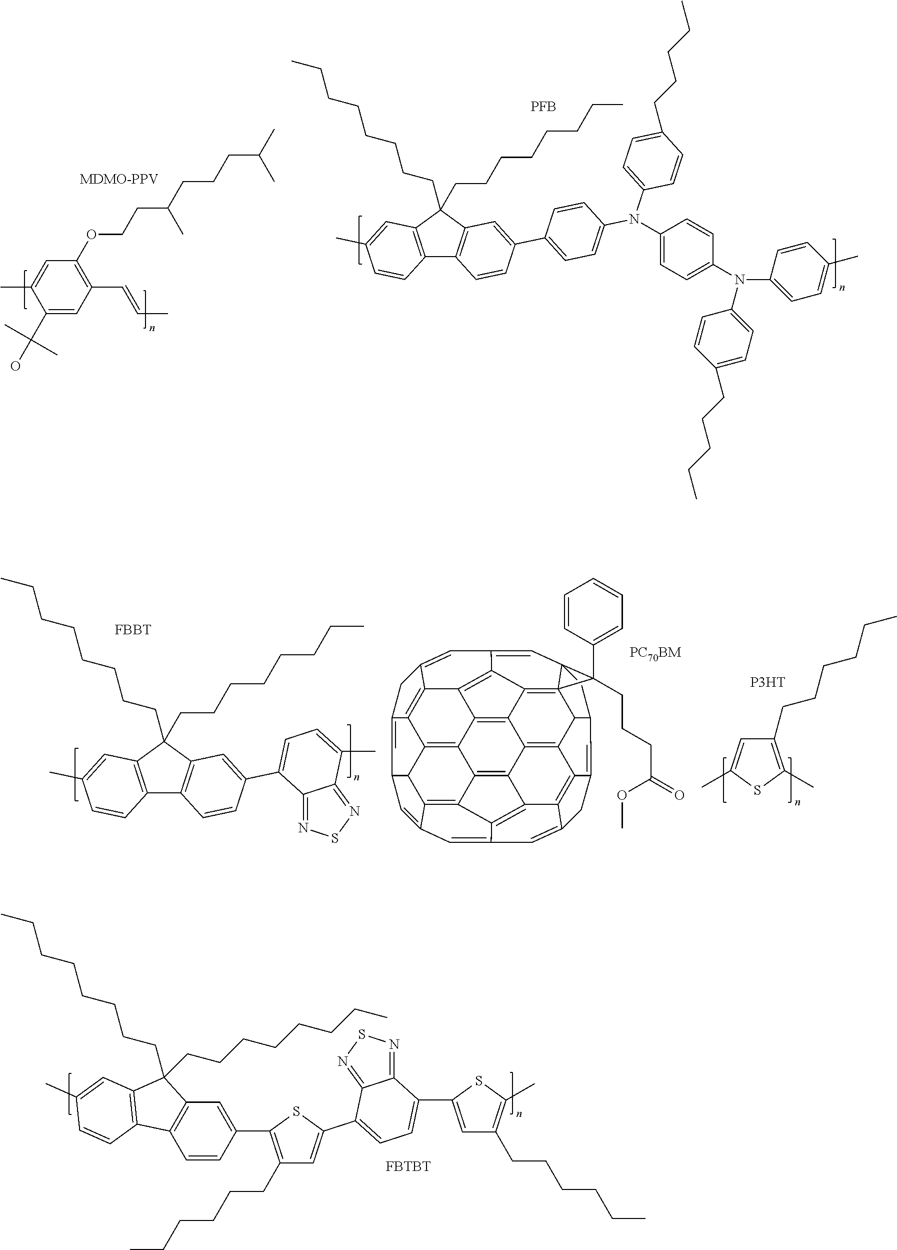

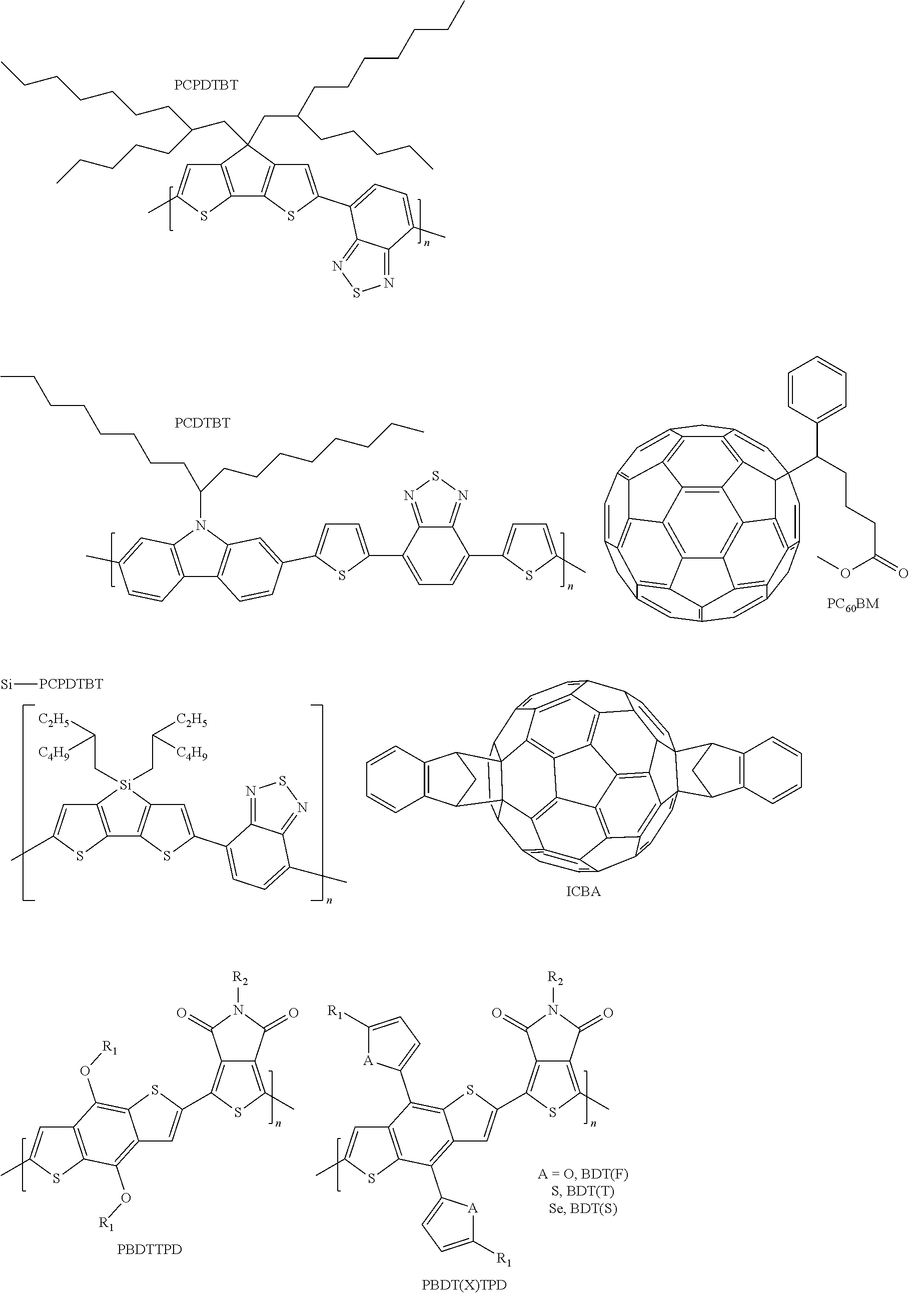

In accordance with one embodiment of the present invention, when P3HT is used as the first polymer and the fullerene-based derivative as the first small molecule, it is preferable that the second polymer which plays a charge-bridging role uses a compound of the following Formula I:

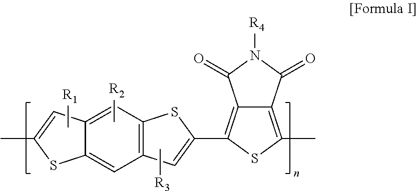

wherein, R₁ to R₄ each independently represent hydrogen, halogen, a cyano group, a nitro group, a hydroxyl group, a substituted or unsubstituted C₁₋₅₀ alkyl, a substituted or unsubstituted C₂₋₅₀ alkenyl group, a substituted or unsubstituted C₂₋₅₀ alkynyl, a substituted or unsubstituted C₁₋₅₀ alkoxy, a substituted or unsubstituted C₃₋₅₀ cycloalkyl, a substituted or unsubstituted C₅₋₅₀ cycloalkenyl, a substituted or unsubstituted C₅₋₅₀ cycloalkynyl, a substituted or unsubstituted C₆₋₅₀ aryl or a substituted or unsubstituted heteroaryl having 5 to 50 nucleus atoms, a substituted or unsubstituted C₅₋₅₀ arylamino or a substituted or unsubstituted C₁₋₅₀ alkylamino; optionally, R₁ to R₄ may be each independently substituted with a C₁₋₅₀ alkyl, C₆₋₅₀ aryl, a heteroaryl having 5 to 50 nucleus atoms or C₇₋₅₀ aralkyl, and wherein the second polymer preferably has a molecular weight of 10000 to 80000.

On the other hand, the term “thin film stability” refers to film uniformity, interface stability with materials of other layers, etc., and has an influence on the drive stability (stable current density, etc.).

Heat resistance of organic electronic materials is greatly associated with a melting point and a glass transition temperature. The heat resistance is directly associated with the molecular rigidity and weight. That is, the higher the molecular weight, the better the heat resistance. If molecules having a substituent capable of freely rotating or a linear aliphatic hydrocarbon substituent are introduced, the heat resistance tends to be reduced compared to those of a similar molecular weight.

The compound of Formula I according to the present invention has advantages of introducing a substituent (R₁ to R₄) in a position irrelevant to conjugation, instead of direct linking to the core, in order to increase solubility. The solubility of the compound represented by Formula I can be increased by properly selecting the substituents R₁ to R₄, thereby improving film processability. For example, the solubility may be increased by adjusting the length of aliphatic substituents, which allows application in a wet film formation process of inkjet, spin-coating, etc.

The active layer of organic solar cells can be formed by employing a conventional method such as spin-coating, dip coating, bar coating, or inkjet printing.

Preferably, a composition for the active layer of organic solar cells according to the present invention may be in a dissolved form in an organic solvent. The organic solvent which can be used here includes chlorobenzene, chloroform, p-xylene, etc.

The active layer of organic solar cells according to the present invention may be formed by spin-coating the composition for the active layer in a solution state, and elevating temperature to evaporate the solvent.

Organic solar cells according to the present invention include a lower electrode layer formed on the substrate, a hole transport layer formed on the lower electrode layer, at least one active layer formed on the hole transport layer, and an upper electrode layer formed on the active layer, as shown in FIG. 1.

The thickness of the active layer is preferably 50 nm 200 nm. If the coating thickness of the active layer is less than 50 nm, a part that can absorb solar light is reduced and thus it is difficult to expect high efficiency. When the thickness exceeds 200 nm, as the thickness increases, charge mobility is reduced, which may reduce the efficiency of solar cells.

### Advantageous Effects of the Invention

Solar cells according to the present invention form a bulk heterojunction (BHJ) active layer using the first polymer, the second polymer, and the first small molecule having energy structures as shown in FIG. 2, in which the second polymer plays a charge-bridging role. As such, even if the content of the first small molecule is reduced for increasing the lifetime of solar cells, the power conversion efficiency (PCE) of solar cells can be greatly increased. Further, the size of the first small molecule aggregates on the surface of thin films can be increased, thereby leading to a change in nanostructure of the BHJ active layer.

### BRIEF DESCRIPTION OF THE DRAWINGS

FIG. 1 is a schematic view of typical solar cells.

FIG. 2 shows an energy structure of the active layer components of ternary solar cells according to the present invention.

FIG. 3 is (a) a schematic diagram of device structure and materials according to the present invention; (b) an optical absorption coefficient (α) of P3HT and PBDTTPD films coated on a quartz substrate; and (c) a flat energy diagram of solar cells shown in the schematic diagram of (a). The energy unit (eV) and minus sign (−) are omitted to avoid crowding figures.

FIG. 4 illustrates one embodiment of the present invention, showing (a) light (100 mW/cm²)J-V curve graphs of devices according to the PBDTTPD content (the unit ‘wt. %’ is omitted), (b) four different cases for possible charge separation(the minus sign ‘−’ is omitted) in the energy axis: (b1) cascade separation graph from P3HT to PC61BM via PBDTTPD, (b2) separation between P3HT and PC61BM, (b3) separation between P3HT and PBDTTPD, and (b4) separation between PBDTTPD and PC₆₁BM.

FIG. 5 illustrates one embodiment of the present invention, showing solar cell parameters (J_{SC}, V_{OC}, FF, PCE, R_{S}, R_{SH}) as a function of the PBDTTPD content (All data was taken from the light J-V curves in FIG. 4a).

FIG. 6 illustrates one embodiment of the present invention, showing (a) wavelength-dependent optical density (OD, normalized at 264 nm) of the bulk heterojunction films according to the PBDTTPD content, and (b) PL spectra of the bulk heterojunction films according to the PBDTTPD content by excitation at 505 nm (top panel) and 555 nm (bottom panel).

FIG. 7 illustrates one embodiment of the present invention, showing (a) AFM images (left: height mode; right: phase mode) of the bulk heterojunction films according to the PBDTTPD content: (a) 0 wt. %, (b) 20 wt. % and (c) 40 wt. %. The root-mean-square (rms) roughness is (a) 0.57 nm, (b) 6.39 nm and (c) 8.32 nm.

FIG. 8 illustrates one embodiment of the present invention, showing TEM images of the bulk heterojunction films according to the PBDTTPD content: (a) 0 wt. %, (b) 20 wt. % and (c) 40 wt. %. The magnification is 12 k for left images and 100 k for right images.

FIG. 9 illustrates one embodiment of the present invention, showing (a) 2D GIXD images and (b) 1D GIXD images (top: OOP, bottom: 1P) for the pristine (P3HT and PBDTTPD) films and the bulk heterojunction films with three different PBDTTPD contents. The major diffraction peaks for each polymer are marked on the top part of (b).

FIG. 10 illustrates one embodiment of the present invention which is graphs showing (a) change of light J-V curves for the device with three different PBDTTPD contents according to the continuous illumination time under 1 sun condition (100 mW/cm²), and (b) variation of J_{SC}, V_{OC}, R_{S} and PCE as a function of illumination time for the devices with three different PBDTTPD contents.

FIG. 11 illustrates one embodiment of the present invention which is graphs showing (a) change of light J-V curves for the devices with three different PBDTTPD contents: (I) after 10 hour exposure to 1 sun condition (100 mW/cm²), (II) thermal treatment for the devices ‘I’ at 100° C. for 1 hour, (III) 10 hour exposure to 1 sun condition for the devices ‘II’, and (b) variation of J_{SC}, V_{OC}, FF and PCE for the devices with three different PBDTTPD contents according to the treatment conditions (I, II, III).

FIG. 12 illustrates one embodiment of the present invention, which is a graph showing a photoelectron (PE) yield spectrum of pristine polymer films (P3HT and PBDTTPD) coated on the ITO-glass substrates. The arrows denote the onset points for each film.

FIG. 13 illustrates one embodiment of the present invention, which is a graph showing semi-logarithmic light (100 mW/cm²) J-V curves for devices according to the PBDTTPD contents: (a) 0 wt. %, (b) 1 wt. %, (c) 5 wt. %, (d) 10, wt. % (e) 20 wt. %, and (f) 40 wt. %.

FIG. 14 illustrates one embodiment of the present invention, which is a graph showing light J-V curves for two binary BHJ devices with the glass/ITO/PEDOT:PSS/active layer/LiF/Al structure. The active layer is (a) P3HT: PC₆₁BM (1:1 by weight) and (b) P3HT: a: PBDTTPD (1:0.7 by weight).

FIG. 15 illustrates one embodiment of the present invention, which is a graph showing dark J-V curves of devices according to the PBDTTPD contents: (a) linear relation, and (b) semi-logarithmic plot.

FIG. 16 illustrates one embodiment of the present invention, which is a graph showing thickness-normalized PL spectra of pristine films (P3HT and PBDTTPD). The excitation wavelength is (a) 505 nm and (b) 555 nm.

FIG. 17 illustrates one embodiment of the present invention, which shows enlarged TEM images of the bulk heterojunction films according to the PBDTTPD content. The approximate size of the PC₆₁BM aggregates is shown in each image.

### MODE FOR INVENTION

Hereinafter, the present invention will be described in detail with reference to the Examples. However, these Examples are for an illustrative purpose, and do not to limit the scope of the present invention.

### Example 1

### Materials and Solutions

The P3HT polymer was purchased from Rieke Metal (regioregularity=91%, weight-average molecular weight=6.2×10⁴ Da, polydispersity index=2.32), while the PBDTTPD polymer was supplied from Solarmer Materials, Inc. PC₆₁BM and PEDOT:PSS (solution, PH500) were purchased from Nano-C and H.C. Starck, respectively. The binary and ternary solutions were prepared using chlorobenzene as a solvent at a solid concentration of 15 mg/ml. The PC61BM content was fixed as 33.3 wt. %, while the weight ratio of P3HT and PBDTTPD was changed in various ways (the overall PEDTTPD content=0, 1, 5, 10, 20, 40 and 60 wt. %). The prepared binary and ternary blend solutions were subjected to vigorous stirring on a hot plate (60° C.) for 24 hours before spin-coating.

### Example 2

### Thin Film and Device Fabrication

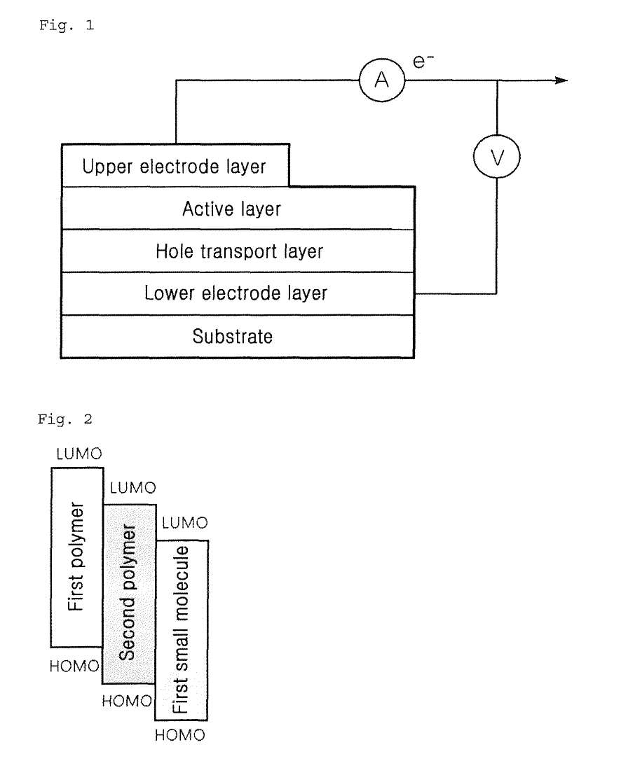

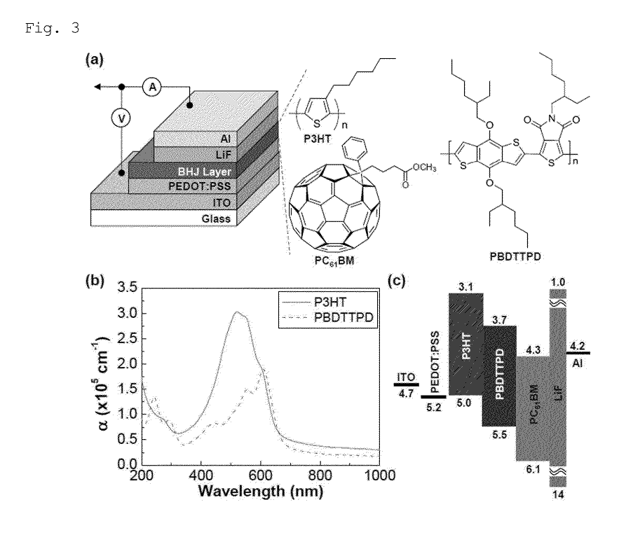

Using the solution from Example 1 to form a thin film of the active layer, a normal type of solar cell structure as shown in FIG. 1 was fabricated.

Prior to device fabrication, patterned indium-tin oxide (ITO)-coated glass substrates were cleaned using acetone and isopropyl alcohol in an ultrasonic cleaner, followed by drying with a nitrogen flow. The dried ITO-glass substrates were further cleaned within a UV-ozone chamber for 20 minutes to remove any remnant of organic residues on the ITO surfaces. On top of the cleaned ITO-glass substrates, the PEDOT:PSS layer (thickness=40 nm) was spin-coated and annealed at a temperature of 200° C. for 15 minutes. The binary and the ternary blend layers were then spin-coated on the PEDOT:PSS layer and soft-baked at a temperature of 60° C. for 15 minutes, thus forming the active layer (thickness=60 nm). Then the film samples were transferred into a vacuum chamber equipped inside an argon-filled glove-box. After pumping down the pressure of vacuum chamber to ˜1×10⁻⁶ Torr, lithium fluoride (LiF, thickness=˜1 nm) and aluminum (Al, thickness=80 nm) were deposited on top of the active layer through a shadow mask. The device active area was 0.9 mm². All devices were subject to thermal annealing at a temperature of 150° C. for 10 minutes and stored inside the same glove-box before measurement. The same film samples as prepared for the device fabrication were used for the AFM and GLXD measurements. The polymeric films were spin-coated on quartz substrates to measure the optical and photoelectron (PE) yield.

### Example 3

### Measurements

The film thickness was measured using a thickness profiler (Alpha Step 200, Tencor Instruments). The optical absorption spectra of films were measured using a UV-visible spectrophotometer (Optizen 2120, MECASYS), and the PL spectra of films were measured with a fluorescence spectrometer (FS-2, SCINCO). The highest occupied molecular orbital (HOMO) energy level of the pristine P3HT and PBDTTPD films was calculated from the ionization potential that was measured using a photoelectron yield spectrometer (AC2, Riken-Keiki). The nanostructure of the film samples was measured using a synchrotron radiation grazing incidence X-ray diffraction (GIXD) system (9A U-SAXS beamline, Pohang Accelerator Laboratory, South Korea) (X-ray wavelength=0.11 nm, incidence angle=0.14° and field-emission transmission electron microscope (FE-TEM) (Titan G2 ChemiSTEM Cs Probe, FEI). The surface morphology of the film samples was measured using an atomic force microscope (AFM, Nanoscope IIIa, Digital Instruments). The performance of the solar cells was measured under 1 sun condition (100 nW/cm²) using a specialized solar cell measurement system equipped with a solar simulator (92250A-1000, Newport-Oriel) and an electrometer (Model 2400, Keithley).

Results and Discussion

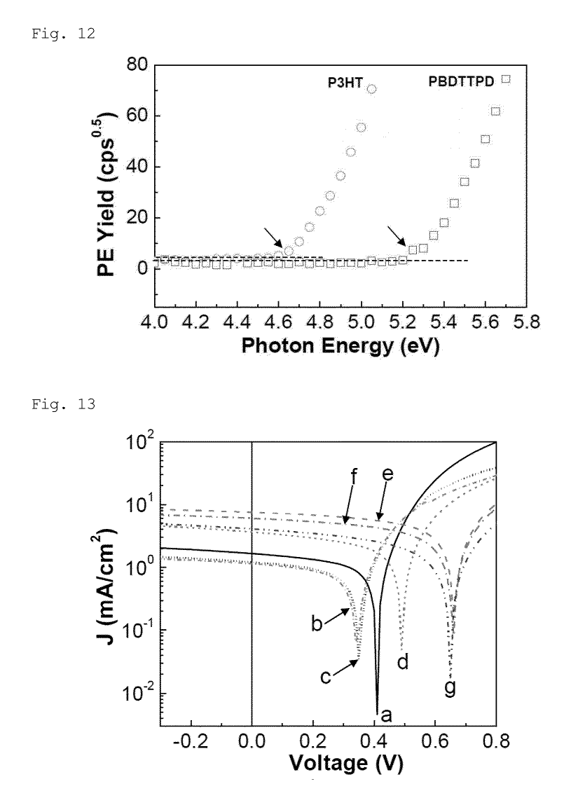

A normal type of solar cell structure is shown in FIG. 1. Looking at the optical absorption spectra in FIG. 3b, the absorption edge for the two polymers is almost similar, but the absorption coefficient (peak) for the PBDTTPD film is considerably lower than that of the P3HT film. Therefore, when the PBDTTPD content is low, the light-harvesting contribution of the PBDTTPD component may be relatively small as compared with the P3HT component. Considering the flat energy band diagram in FIGS. 3c and 12, the PBDTTPD component can take electrons first from the P3HT component by charge separation process and then deliver electrons to the PC61BM component by charge transport process (At the same time the hole transport may follow in the counter direction of the electron transport). In other words, the PBDTTPD component is supposed to play a bridge role for charge transfer/transport between the P3HT component and the PC61BM component. The PBDTTPD component itself can also absorb a solar light and the photogenerated electrons can be transferred to the PC61BM component. Here, the number of electrons is dependent on the PBDTTPD content (Similarly, the photogenerated holes in the PBDTTPD component can be transferred to the P3HT component).

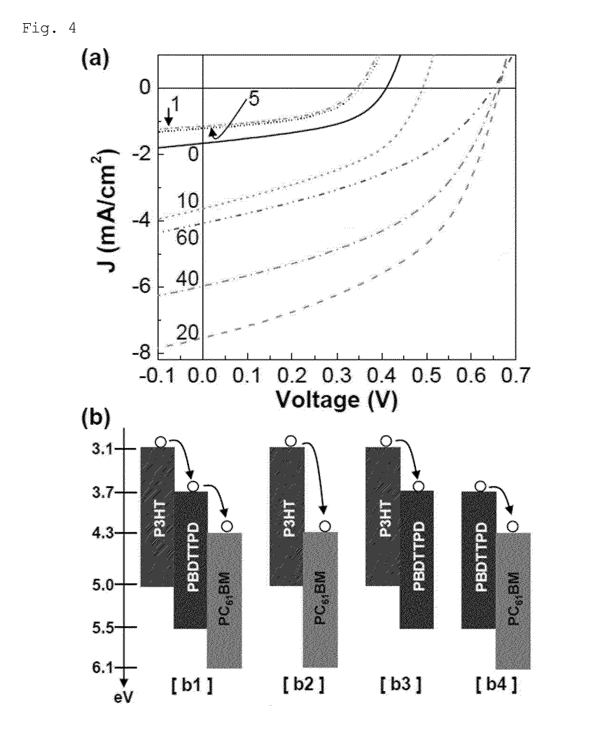

In order to investigate the influence of the PBDTTPD addition, the weight ratio of P3HT and PC₆₁BM (PC₅₁BM=33.3 wt. %) was fixed and the PBDTTPD content was varied up to 60 wt. %. As observed from the current density-voltage (J-V) curves under solar light illumination (FIG. 4a), the P3HT:PC₆₁BM solar cell without the PBDTTPD polymer resulted in very low short circuit current density (J_{SC}=1.6 mA/cm²), and the V_{OC} was also low (0.4 V) (see Table 1 and FIG. 13).

Table 1 summarizes solar cell performances according to the PBDTTPD content (All data were taken from the light J-V curves in FIG. 3).

TABLE 1

| | PBDTTPD (wt. %) | | | | | | |
|---|---|---|---|---|---|---|---|
| | 0 | 1 | 5 | 10 | 20 | 40 | 60 |
| J_{SC} (mA/cm²) | 1.655 | 1.142 | 1.210 | 3.638 | 7.551 | 5.985 | 4.074 |
| V_{OC} (V) | 0.40 | 0.34 | 0.35 | 0.49 | 0.66 | 0.65 | 0.64 |
| FF (%) | 48.7 | 48.5 | 48.2 | 43.2 | 47.3 | 45.7 | 40.1 |
| PCE (%) | 0.322 | 0.188 | 0.204 | 0.770 | 2.358 | 1.779 | 1.045 |
| R_{S} (kΩ cm²) | 0.59 | 0.77 | 0.71 | 0.32 | 0.21 | 0.30 | 0.58 |
| R_{SH} (kΩ cm²) | 8.0 | 13.2 | 12.1 | 3.7 | 3.4 | 3.2 | 3.9 |

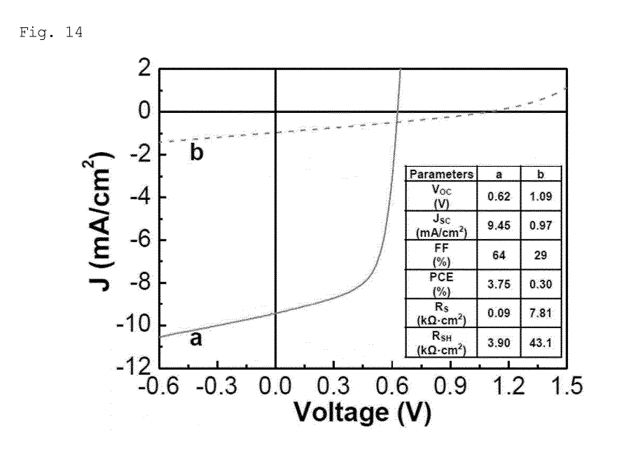

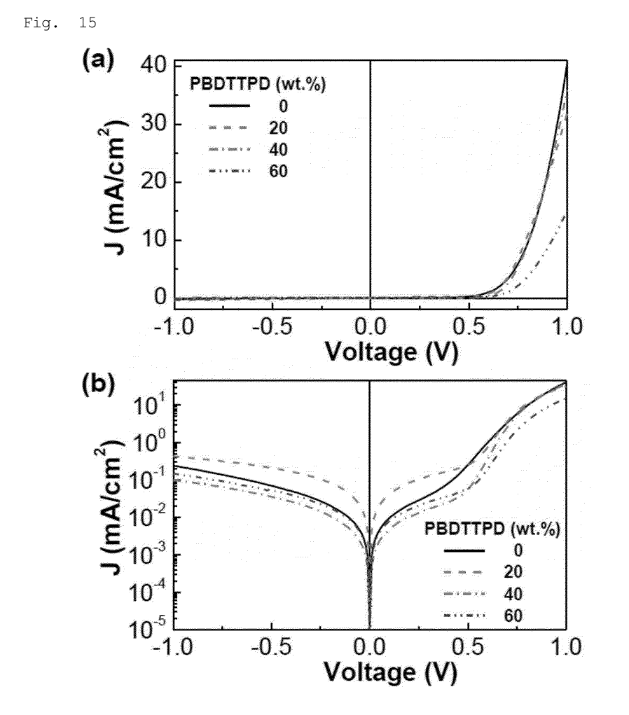

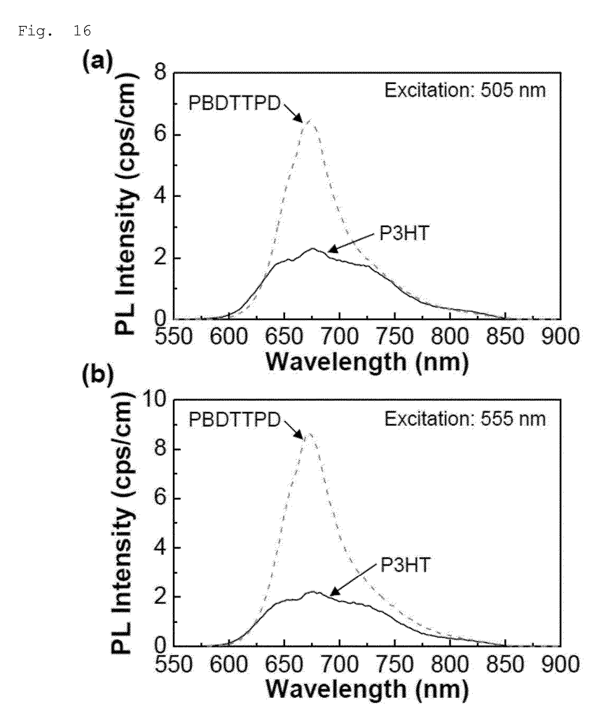

When a small amount of the PBDTTPD polymer (1 wt. % and 5 wt. %) was added, the light J-V curves became even worse leading to much lower J_{SC} and V_{OC}. However, interestingly, when 10 wt. % of PBDTTPD was added, the J_{SC} (3.6 mA/cm²) and V_{OC} (0.49V) values considerably increased. In particular, when the PBDTTPD content was 20 wt. %, the J_{SC} and V_{OC} values reached ˜7.6 mA/cm² and 0.66 V. Almost a 5-fold increase of the J_{SC} value (from 1.6 mA/cm² to 7.6 ma/cm²) shows that the PBDTTPD component did play an efficient bridging role in transferring electrons from the P3HT component to the PC₆₁BM component. This is because 20 wt. % of PBDTTPD is too small to generate such high photocurrent when it comes to the quite low absorption coefficient as discussed in FIG. 3b. However, there is need to pay attention to the V_{OC} value (0.66 V), which is higher than typical V_{OC} (˜0.62 V) for the best optimized P3HT:PC₆₁BM solar cells using the present batch of P3HT (see FIG. 14a). This suggests that the addition of the PBDTTPD did additionally contribute to the increased V_{OC}, which is theoretically possible if the electrons in the PBDTTPD component are directly collected to the A1 electrode (see FIG. 4b). However, as shown in FIG. 14, the performance of the P3HT:PBDTTPD solar cells is very poor such that the PBDTTPD component alone, as an electron acceptor, cannot deliver such a high photocurrent. Therefore, a harmonic effect was expected by both PBDTTPD and PC₆₁BM, which may be an enhanced electron transport for the PBDTTPD and PC₆₁BM phases. This is evidenced from the noticeably (3-fold) reduced series resistance (R_{S}) from ˜0.62 kΩ·cm² to ˜0.2 kΩ·cm² (see Table 1). However, further increasing the PBDTTPD content did rather begin to reduce both J_{SC} and V_{OC} but the device performance of all ternary solar cells (P3HT:PBDTTPD:PC₆₁BM) was still much better than the binary solar cells (P3HT:PC₆₁BM).

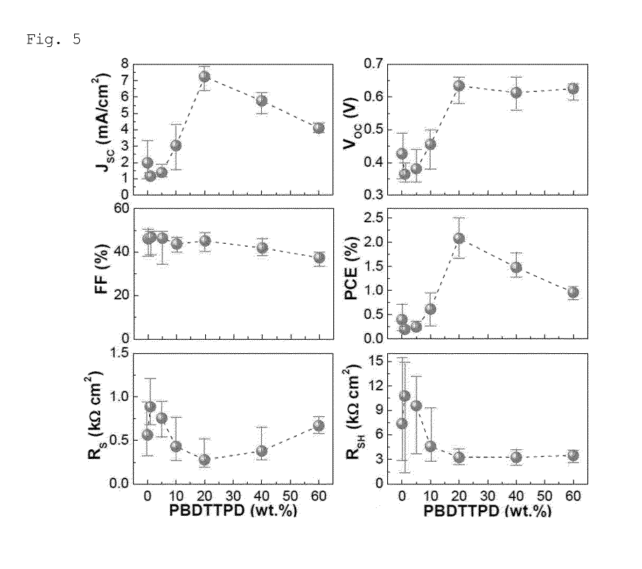

The detailed trend of device performances is shown in FIG. 5. Here, the J_{SC} value was maximum at 20 wt. % of PBDTTPD and then noticeably decreased by further increasing the PBDTTPD content, whereas the V_{OC} decrease was relatively slighter than the J_{SC} decrease. These results imply that the number of photogenerated charges was decreased by increasing the PBDTTPD content because of the low optical absorption coefficient of PBDTTPD (see FIG. 3b). The fill factor (FF) was not strikingly changed by the addition of PBDTTPD, but big changes were made for R_{S} and shunt resistance (R_{SH}). When the PBDTTPD was added in a small amount (<10 wt. %), the poor PCE can be ascribed to the increased R_{S}. From the present PBDTTPD addition experiments, more than 7-fold improved PCE has been obtained by adding 20 wt. % of PBDTTPD.

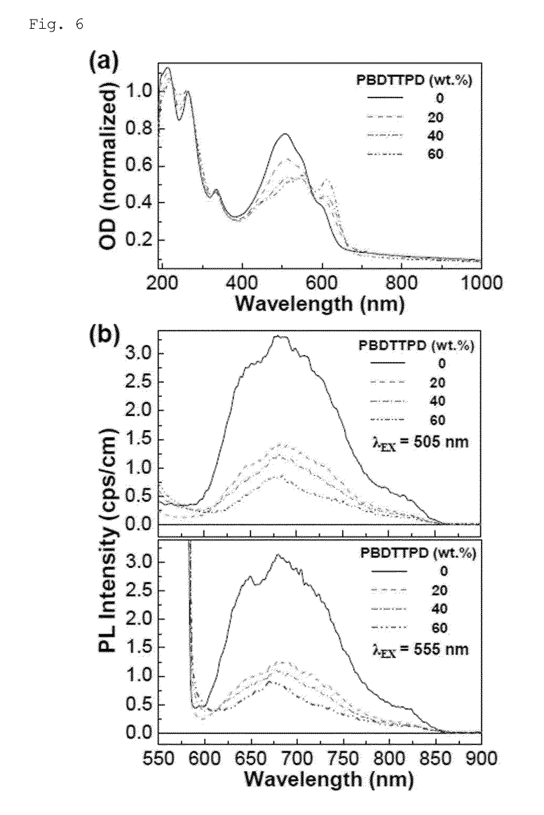

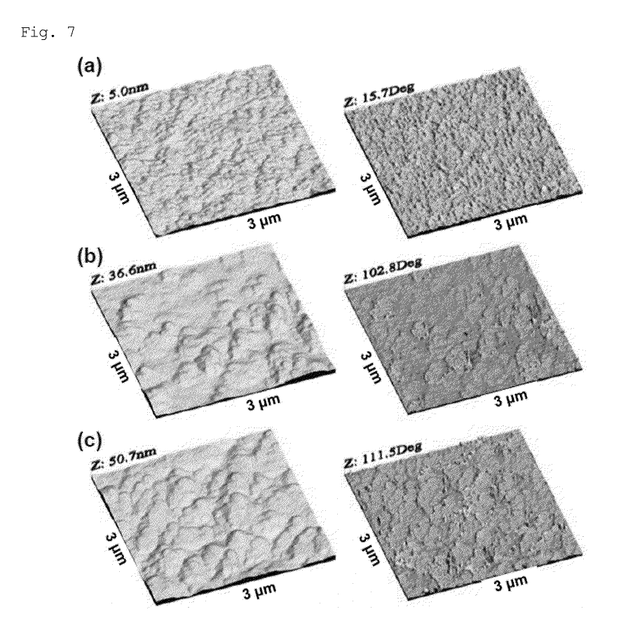

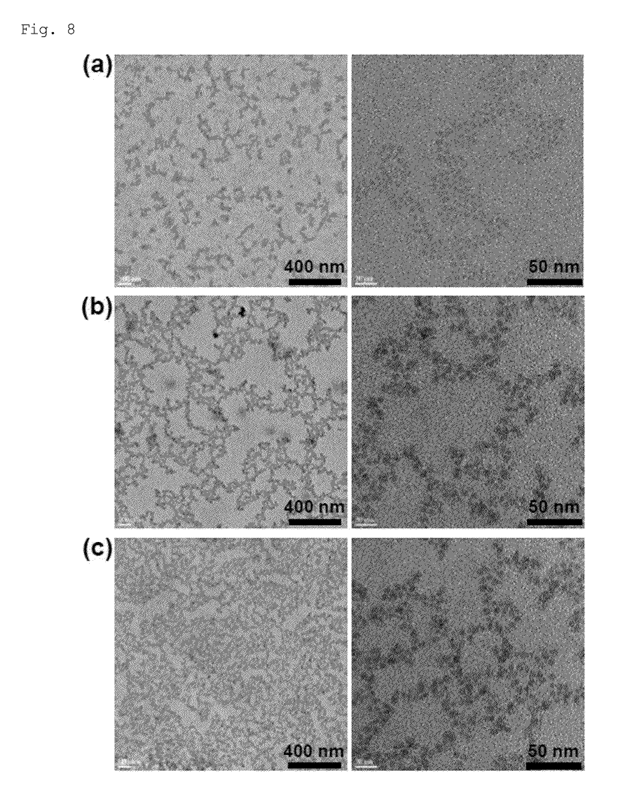

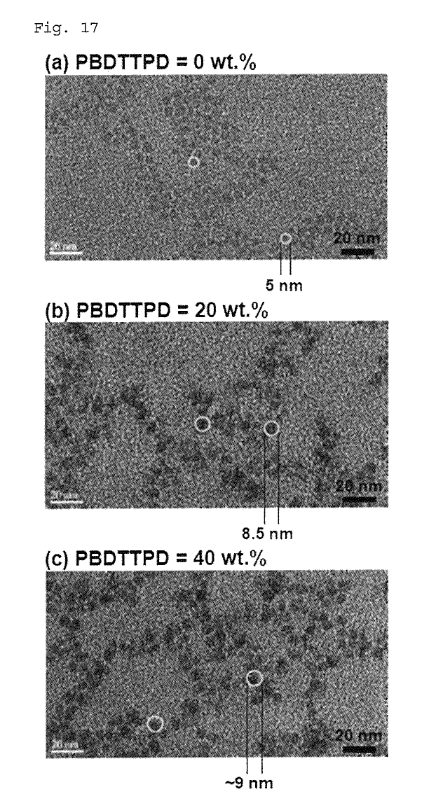

In order to understand the significantly improved device performance in detail, the optical absorption and photoluminescence (PL) spectra were first investigated. As shown in FIG. 6a, as the PBDTTPD content increased, the P3HT absorption part was decreased but the PBDTTPD absorption part was increased. Considering that the solar light intensity is stronger at 500 nm (wavelength) than at 620 nm, the number of electrons absorbed by the binary blend film (P3HT:PC₆₁BM) is slightly higher than or similar to that by the ternary blend films (P3HT: PBDTTPD: PC₆₁BM) when it comes to the absorption area depending on the PBDTTPD contents. These results suggest that the light harvesting is not the reason for such huge increase in the J_{SC} value by adding the PBDTTPD polymer. Next, looking at the PL spectra (FIG. 6b), the PL intensity was greatly reduced by adding the PBDTTPD polymer regardless of excitation wavelengths. As shown in FIG. 16, the thickness-normalized PL intensity was higher for the PBDTTPD polymer than the P3HT polymer. These results mean that there was an additional charge separation event between the P3HT component and the PBDTTPD component in addition to that between the P3HT component and the PC₆₁BM component. In particular, the higher the PBDTTPD content, the lower the PL intensity. This result reflects that the charge separation (charge transfer from the P3HT component to the PBDTTPD component) became efficient as the PBDTTPD content increases, but it is opposite to the J_{SC} trend that was decreased as the PBDTTPD content increased further from 20 wt. % up to 60 wt. %. Therefore, the charge (electron) transport may be a limiting factor at higher PBDTTPD contents as observed from the increased R_{S} values (see FIG. 5).

Next, the nanomorphology of the BHJ films according to the PBDTTPD content was investigated. As shown from the atomic force microscope (AFM) images in FIG. 7, the surface morphology became relatively coarse as the PBDTTPD content increased. The surface roughness was significantly increased from 0.57 nm (P3HT:PC₆₁BM) to 6.39 nm (P3HT: PBDTTPD: PC₆₁BM at 20 wt. % of PBDTTPD). Considering that the J_{SC} was greatly increased by adding the PBDTTPD polymer, this morphology change might contribute to making better charge percolation paths in the BHJ films. Interestingly, as shown from the transmission electron microscope (TEM) images in FIG. 8, the addition of the PBDTTPD led not only to a change in the surface morphology but also a change in the PC₆₁BM segregation morphology inside the BHJ films from the dark areas in TEM images.

As observed from the left side TEM images (low magnification) in FIG. 8, the apparent density (amount) of PC₆₁BM molecules was increased as the PBDTTPD content increased. From the high magnification TEM images (right side), it has been found that the size of the PC₆₁BM aggregates became bigger for the ternary films (8.5˜9 nm) than the binary film (˜5 nm) (see also FIG. 17). The PC₆₁BM molecules were slightly enriched toward the surface of films by the addition of the PBDTTPD, leading to the formation of bigger PC₆₁BM aggregates, which is partly responsible for the coarse morphology as observed from the AFM images. Hence, it is considered that the surface enrichment of PC₆₁BM had a positive influence on the performance of the present normal type solar cells and the relatively bigger PC₆₁BM aggregates by the presence of PBDTTPD did also help better electron transport.

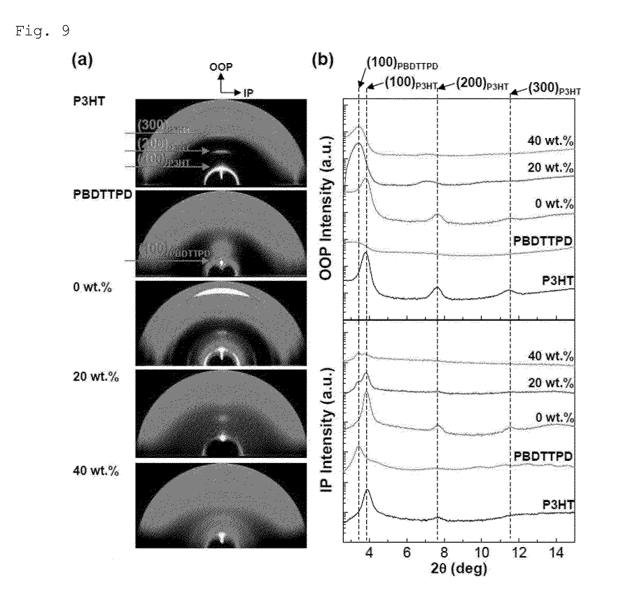

Considering the surface and internal segregation morphology changes in FIGS. 7 and 8, it can be anticipated that the molecular chain stacking in the BHD films might be affected by the addition of the PBDTTPD. In order to investigate this point, the synchrotron radiation grazing incidence X-ray diffraction (GIXD) measurement for the binary and ternary blend films was carried out. As observed from the 2D GIXD images (FIG. 9a), the P3HT film showed typical Debye rings with high order diffractions up to (300) which are pronounced in the direction of our-of-plane (OOP). However, the PBDTTPD film showed only (100) diffraction ring but no clear higher order diffractions, which is observed from the 10 profiles in FIG. 9b. This result suggests that the PBDTTPD polymer is less crystalline than the P3HT polymer. As expected, the high order diffraction feature of the P3HT component in the BHJ films was weakened as the PBDTTPD content increased. In addition, when adding only 20 wt. % of PBDTTPD, the (100) peak position was obviously moved toward lower diffraction angles (from 2θ=3.78° to 2θ=3.40°). This result implies that adding only 20 wt. % of PBDTTPD led to a significant change in the P3HT chain stacking, which is again closely related with the huge change in the surface and internal segregation morphology as discussed in FIGS. 7 and 8. As a result, the d-spacing for molecular chain stacking became larger for the ternary blend films (˜1.85 nm) than the binary blend film (˜1.65 nm) (see Table 2).

Table 2 shows d-spacing values for pristine (P3HT and PBDTTPD) and bulk heterojunction(BHJ) films with different PBDTTPD contents. (All data were taken from GIXD from FIG. 9).

TABLE 2

| Films | Constituent | Direction | d-spacing (\acute{Å}) |
|---|---|---|---|
| Pristine | P3HT | OOP, IP | 16.42 |
| Pristine | PBDTTPD | OOP, IP | 18.75 |
| BHJ | P3HT | OOP | 16.74 |
| PBDTTPD (wt. %) = | PBDTTPD | IP | 16.57 |
| 0 wt. % | | | |
| BHJ | P3HT | OOP | N/M |
| PBDTTPD (wt. %) = | PBDTTPD | OOP | 18.53 |
| 20 wt. % | P3HT | IP | 16.49 |
| | PBDTTPD | IP | 18.35 |
| BHJ | P3HT | OOP | N/M |
| PBDTTPD (wt. %) = | PBDTTPD | OOP | 18.70 |
| 40 wt. % | P3HT | IP | 16.74 |
| | PBDTTPD | IP | 18.70 |

However, interestingly, the larger d-spacing did not negatively but positively affected the device performance. This result may reflect that the devices with low fullerene contents are strongly influenced by the proper functioning of electron accepting components (PBDTTPD and PC61BM) rather than electron donating (p-type) component (P3HT) in a viewpoint of relative energy band levels.

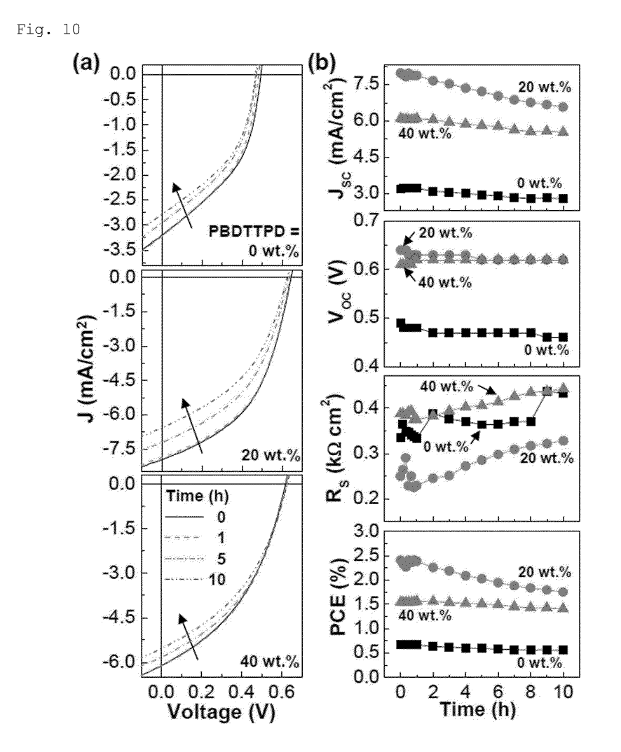

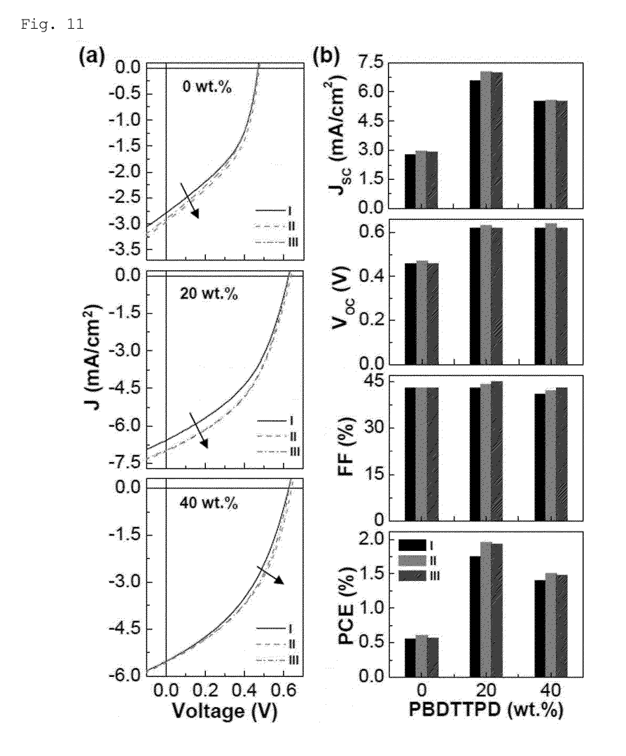

Finally, the stability of the solar cells before and after the addition of PBDTTPD was also investigated. First, the initial performance change was investigated by exposing the devices under 1 sun (100 mW/cm²) condition for 10 hours. As shown from the J-V curves in FIG. 10a, all devices showed gradually decreased J_{SC} but the V_{OC} reduction was relatively small. Interestingly, the V_{OC} change was relatively stable for the ternary solar cells compared to the binary solar cell (The binary solar cell showed on-going V_{OC} decreasing trend whereas the V_{OC} value was leveled off for the ternary solar cells). Although the J_{SC} drop was relatively larger for the ternary solar cell with 20 wt. % of PBDTTPD, the PCE was still much higher for the ternary solar cell with 20 wt. % of PBDTTPD than the binary solar cell even after a 10 hour test. In addition, the ternary solar cell containing 40 wt. % of PBDTTPD exhibited a fairly stable PCE (only 0.14% PCE decrease after 10 hours). Subsequently, the devices were exposed to the 1 sun condition for 10 hours, at a temperature of 100° C. for 1 hour and then thermally treated. As shown in FIG. 11, the performance of all devices was improved by thermal annealing. However, the extent of performance recovery was more pronounced for the ternary solar cells (20 wt. % PBDTTPD: from PCE=1.75% to 1.95%; 40 wt. % PBDTTPD: from PCE=1.40% to 1.50%) than the binary solar cell (from PCE=0.56% to 0.61%). Considering the initial stability change and the recovery trend by thermal treatment, the addition of PBDTTPD is considered as an effective approach to improve both stability and efficiency in polymer:fullerene solar cells with low fullerene contents.

### CONCLUSIONS

The charge-bridging polymer, PBDTTPD, was added to the P3HT:PC₆₁BM films of solar cells with low PC₆₁BM content (33.3 wt. %) of which the solar cells show only ˜0.3% PCE. At the low PBDTTPD contents of less than 10 wt. %, the device performance became slightly worse than the control device (P3HT: PC₆₁BM), but it was noticeably improved by further addition of PBDTTPD. When 20 wt. % of PBDTTPD was added, the PCE reached ˜2.4% which is more than 7-fold enhanced PCE. Further the addition of PBDTTPD (40 wt. % and 60 wt. %) did slightly degrade the device performance but the resulting PCE values were still higher than the binary solar cell (P3HT:PC₆₁BM). This remarkably enhanced performance has been attributed to the bridging role of PBDTTPD for efficient charge transfer/transport between P3HT and PC₆₁BM domains. The morphology measurements showed that the addition of PBDTTPD induced the enrichment of PC₆₁BM molecules toward the film surfaces (the PC₆₁BM aggregates became bigger), leading to better vertical alignment of p-n junctions. In particular, it is very interesting that the device's performance was significantly enhanced even though the P3HT stacking was considerably destroyed by adding 20 wt. % of PBDTTPD as evidenced from the GIXD measurement. The initial stability test showed that the PCE of the ternary solar cells with the PBDTTPD polymer was still higher than the binary solar cell even after 10 hour illumination of simulated solar light. In addition, the performance of the ternary solar cell with 20 wt. % of PBDTTPD, which was exposed to 1 sun condition for 10 hours, was relatively well recovered by thermal treatment, though other devices did also show similar recovery trend.

What is claimed is:

1. A composition for active layer of organic solar cell comprising
a first polymer which absorbs light to form excitons,
a second polymer which plays a charge-bridging role, and
a first small molecule which is an electron accepting material,
wherein LUMO energy level of the second polymer is present between LUMO energy level of the first polymer and LUMO energy level of the first small molecule,
HOMO energy level of the second polymer is present between HOMO energy level of the first polymer and HOMO energy level of the first small molecule, and
the content of the first small molecule is 10 wt. % to 45 wt. % based on the total weight of the first polymer, the second polymer and the first small molecule.

2. The composition for active layer of organic solar cell according to claim 1, wherein the content of the second polymer is 10 wt. % to 60 wt. % based on the total weight of the first polymer, the second polymer and the first small molecule.

3. The composition for active layer of organic solar cell according to claim 1, wherein the size of the first small molecule aggregates on the surface of the active layer is increased by addition of the second polymer, thereby increasing the surface roughness.

4. The composition for active layer of organic solar cell according to claim 1, wherein the first polymer is poly(3-hexylthiophene)(P3HT), the first small molecule is a fullerene derivative, and the second polymer which plays a charge-bridging role is a polymer of the following Formula I: 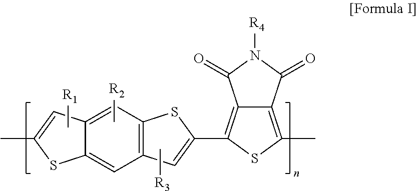
wherein, R₁ to R₄ each independently represent hydrogen, halogen, a cyano group, a nitro group, a hydroxyl group, a substituted or unsubstituted C₁₋₅₀ alkyl, a substituted or unsubstituted C₂₋₅₀ alkenyl group, a substituted or unsubstituted C₂₋₅₀ alkynyl, a substituted or unsubstituted C₁₋₅₀ alkoxy, a substituted or unsubstituted C₃₋₅₀ cycloalkyl, a substituted or unsubstituted C₅₋₅₀ cycloalkenyl, a substituted or unsubstituted C₅₋₅₀ cycloalkynyl, a substituted or unsubstituted C₆₋₅₀ aryl or a substituted or unsubstituted heteroaryl having 5 to 50 nucleus atoms, a substituted or unsubstituted C₅₋₅₀ arylamino or a substituted or unsubstituted C₁₋₅₀ alkylamino; optionally, R₁ to R₄ may be each independently substituted with a C₁₋₅₀ alkyl, C₆₋₅₀ aryl, a heteroaryl having 5 to 50 nucleus atoms or C₇₋₅₀ aralkyl, and wherein the second polymer has a molecular weight of 10000 to 80000.

5. An organic solar cells in which an active layer is disposed between two electrodes,
the active layer comprising a first polymer which absorbs light to form excitons, a second polymer which plays a charge-bridging role, and a first small molecule which is an electron accepting material, wherein:
LUMO energy level of the second polymer is present between LUMO energy level of the first polymer and LUMO energy level of the first small molecule;
HOMO energy level of the second polymer is present between HOMO energy level of the first polymer and HOMO energy level of the first small molecule; and the content of the first small molecule is 10 wt. % to 45 wt. % based on the total weight of the first polymer, the second polymer and the first small molecule.

6. The organic solar cell according to claim 5, wherein the content of the second polymer is 10 wt. % to 60 wt. % based on the total weight of the first polymer, the second polymer and the first small molecule.

7. The organic solar cell according to claim 5, wherein the first polymer is poly(3-hexylthiophene)(P3HT), the first small molecule is a fullerene derivative, and the second polymer which plays a charge-bridging role is a polymer having the following Formula I: 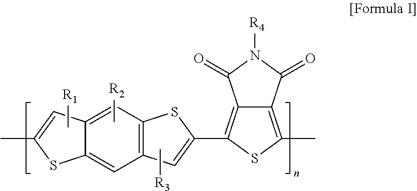
wherein, R₁ to R₄ each independently represent hydrogen, halogen, a cyano group, a nitro group, a hydroxyl group, a substituted or unsubstituted C₁₋₅₀ alkyl group, a substituted or unsubstituted C₂₋₅₀ alkenyl group, a substituted or unsubstituted C₂₋₅₀ alkynyl, a substituted or unsubstituted C₁₋₅₀ alkoxy, a substituted or unsubstituted C₃₋₅₀ cycloalkyl, a substituted or unsubstituted C₅₋₅₀ cycloalkenyl, a substituted or unsubstituted C₅₋₅₀ cycloalkynyl, a substituted or unsubstituted C₆₋₅₀ aryl or a substituted or unsubstituted heteroaryl having 5 to 50 nucleus atoms, a substituted or unsubstituted C₅₋₅₀ arylamino or a substituted or unsubstituted C₁₋₅₀ alkylamino; optionally, R₁ to R₄ may be each independently substituted with a C₁₋₅₀ alkyl, C₆₋₅₀ aryl, a heteroaryl having 5 to 50 nucleus atoms or C₇₋₅₀ aralkyl, and wherein the second polymer has a molecular weight of 10000 to 80000.

8. A kit for forming active layer of organic solar cell comprising:
a first polymer which absorbs light to form excitons;
a second polymer which plays a charge-bridging role; and
a first small molecule which is an electron accepting material,
wherein LUMO energy level of the second polymer is present between LUMO energy level of the first polymer and LUMO energy level of the first small molecule, and
HOMO energy level of the second polymer is present between HOMO of the first polymer and HOMO of the first small molecule.
